(19) United States
(12) Patent Application Publication
(10) Pub. No.: US 2020/0180508 A1
(43) Pub. Date: Jun. 11, 2020

(54) METHOD FOR DETECTING A SHORT CIRCUIT IN A LIGHT SOURCE OF A VEHICLE

(71) Applicant: HELLA GmbH & Co. KGaA, Lippstadt (DE)

(72) Inventor: Michael FELDGEN, Lippstadt (DE)

(73) Assignee: HELLA GmbH & Co. KGaA, Lippstadt (DE)

(21) Appl. No.: 16/705,845

(22) Filed: Dec. 6, 2019

(30) Foreign Application Priority Data
Dec. 7, 2018 (DE) 10 2018 131270.9

(51) Int. Cl. B60Q 11/00; G07C 5/08; G01R 31/00; G01R 31/52

(52) U.S. Cl. CPC B60Q 11/005; G07C 5/0816; B60Q 1/04; G01R 31/52; G01R 31/007

(57) ABSTRACT

A circuit arrangement for detecting a short circuit in at least one light emitting diode of a lighting unit of a vehicle comprising a plurality of light emitting diodes connected in series, comprising a reference light emitting diode, a voltage sensing unit for determining a reference voltage at the reference light emitting diode and in each case one diode voltage at one of the light emitting diodes of the lighting unit, and a detection unit for detecting a short circuit in a light emitting diode on the basis of the reference voltage and a single diode voltage, wherein the reference light emitting diode and the light emitting diodes are identical light emitting diodes. Furthermore, the invention relates to a corresponding method for detecting a short circuit, a computer program, a memory and a vehicle.

This nonprovisional application claims priority under 35 U.S.C. § 119(a) to German Patent Application No. 10 2018 131270.9, which was filed in Germany on Dec. 7, 2018, and which is herein incorporated by reference.

### BACKGROUND OF THE INVENTION

### Field of the Invention

The present invention relates to a circuit arrangement and to a method for detecting a short circuit in a light emitting diode. In addition, the invention relates to a computer program for detecting a short circuit in a light emitting diode, a memory with a computer program stored thereon and a vehicle in which a short circuit in a light emitting diode can be detected.

### Description of the Background Art

The complexity of lighting circuits in the automotive sector is constantly increasing. Current lighting systems are no longer limited to individual light sources, but often have multiple light sources that achieve the required or desired lighting effect, for example in the form of multiple light emitting diodes connected in series. That is, to generate the desired light function, several light emitting diodes are now connected in series with each other and supplied with a common supply voltage via a constant current source.

As described in the German patent application DE 10 2008 008 217 A1, a failure of light sources in vehicle headlights or lighting units for motor vehicles usually occurs due to interruptions, such as in lamps with a filament. Even when using light emitting diodes as light sources, the failure of one or more light emitting diodes is usually due to an interruption. However, although less likely, it could also be due to a short circuit of one or more of the light emitting diodes.

The automotive industry is calling for the ability to detect the short circuit of even a single light source. Due to large voltage tolerances, however, in a series connection of multiple light emitting diodes in generic circuit arrangements, it is possible only with difficulty and with a correspondingly great expense, i.e., only by means of complex electronics, to detect a short circuit of a single light emitting diode using total voltage monitoring of a series connection of the light emitting diodes. A generic method for determining a short circuit can be found for example in DE 10 2014 112 176 A1, which corresponds to U.S. Pat. No. 9,883,565.

According to DE 10 2008 008 217 A1, a circuit arrangement for detecting a short circuit of one or more light emitting diodes is proposed, wherein two or more light emitting diodes are provided for realizing at least one light function for a headlight or a lighting unit of a motor vehicle, and the light emitting diodes are connected to each other in series and are connected to a supply voltage source via a constant current source. According to DE 10 2008 008 217 A1, each light emitting diode is assigned an electronic switch.

Wherein furthermore a voltage dropping across the light emitting diodes is supplied to a control input of the switch assigned to the respective light emitting diode, and wherein the switch changes from an open state/closed state during normal operation of the associated light emitting diode to a closed state/open state in the event of a short circuit of the light emitting diode and the resulting change in the light emitting diode voltage drop is detectable.

However, in view of the available prior art, there is still a desire for an even simpler and/or more accurate system for detecting a short circuit in a light emitting diode of a generic lighting unit.

### SUMMARY OF THE INVENTION

It is therefore an object of the present invention to provide a circuit arrangement via which a short circuit of a light emitting diode in a lighting unit having a plurality of light emitting diodes connected in series can be detected in a simple and reliable manner. It is another object of the invention to provide a corresponding method and a computer program product for the simple and reliable detection of a short circuit in a light emitting diode in such a lighting unit. Moreover, it is an object of the invention to provide a memory on which such a computer program product is stored, as well as a vehicle with a circuit arrangement designed therein for the simple and reliable detection of a short circuit in a light emitting diode of a series connection with a plurality of light emitting diodes.

According to an exemplary embodiment of the present invention, a circuit arrangement is provided for detecting a short circuit in at least one light emitting diode of a lighting unit of a vehicle, which comprises a plurality of light emitting diodes connected in series. The circuit arrangement has a reference light emitting diode and a voltage sensing unit for determining a reference voltage at the reference light emitting diode and in each case a diode voltage at one of the light emitting diodes of the light emitting unit. In addition, the circuit arrangement has a detection unit for detecting a short circuit in a light emitting diode on the basis of the reference voltage and a single diode voltage, wherein the reference light emitting diode and the light emitting diodes are identical light emitting diodes.

With the aid of the circuit arrangement according to the invention, in particular with the aid of the reference light emitting diode, a short circuit in a light emitting diode can be easily and reliably detected or determined. On the basis of the reference voltage and an associated diode voltage, it can be easily determined whether or not there is a short circuit at the corresponding light emitting diode. For example, if the reference voltage is 3V and the associated diode voltage is also 3V, it can be assumed that there is no short circuit. If the reference voltage is 3V and the associated diode voltage is significantly lower, the typical forward voltage being approximately 10% of 3V, it can be assumed that there is a short circuit. Thus, the detection unit could be configured and adapted to detect a short circuit based on a comparison between the reference voltage and the diode voltage. The comparison may include a subtraction or addition between the reference voltage and the one diode voltage.

The proposed circuit arrangement can not only determine whether there is a short circuit at one of the light emitting diodes of the lighting unit, but also at which of the light emitting diodes the short circuit is present.

The reference light emitting diode can be a light emitting diode that is not used in the circuit arrangement and/or in the vehicle as a light, but exclusively as a reference value transmitter for providing the reference voltage. When determining the reference voltage, the reference light emitting diode is measured to ground. When determining the diode voltage, a light emitting diode in each case is measured to ground. The light emitting diodes are arranged in different channels. That is, in each case a specific diode voltage is determined at a specific light emitting diode in a specific channel. In other words, each light emitting diode of which the diode voltage is detected is disposed in a different channel. The diode voltage can be understood to be a forward voltage at one of the light emitting diodes.

Since the reference light emitting diode and the light emitting diodes are identical light emitting diodes, it can be understood that the reference light emitting diode is of the same type as the light emitting diodes being checked for a possible short circuit.

It is also possible that, in a circuit arrangement, the detection unit is configured and adapted to compare the reference voltage with in each case one of the diode voltages, to determine a differential voltage between the reference voltage and the respective diode voltage based on the comparison, to compare the detected differential voltage in each case with a predefined threshold voltage and to detect a short circuit in a light emitting diode when the differential voltage is greater than the threshold value. On the basis of the differential voltage in relation to the threshold value, it is possible to detect in a simple and unambiguous manner as well as with simple calculation steps and correspondingly quickly whether or not there is a short circuit at one of the light emitting diodes.

Furthermore, it is possible with a circuit arrangement according to the invention that the circuit arrangement has a shut-off unit for switching off, in particular for automatically switching off the lighting unit on the basis of the reference voltage and a single diode voltage. By means of the shut-off unit, it is possible to prevent further light emitting diodes and/or further components of the circuit arrangement or of the vehicle from being damaged or destroyed by a short circuit in a light emitting diode. What is written above in respect of detecting the short circuit applies in an analogous manner with regard to the use of the reference voltage and the individual diode voltage.

It is also possible that in a circuit arrangement according to the present invention, a signal output unit for outputting a warning signal for switching off the lighting unit on the basis of the reference voltage and a single diode voltage is provided. With the warning signal for switching off the lighting unit or the recommendation to switch off the lighting unit, a user of the vehicle can promptly arrange for repair or replacement of the lighting unit before the lighting unit possibly fails completely in an unfavorable situation. The signal output unit may be configured and designed to send the warning signal to a signal converter of the circuit arrangement or the vehicle for the acoustic and/or optical output of the warning signal to the user of the vehicle or the circuit arrangement.

According to a further aspect of the present invention, a method is provided for detecting a short circuit in at least one light emitting diode of a lighting unit of a vehicle comprising a plurality of light emitting diodes connected in series by means of a reference light emitting diode, wherein the reference light emitting diode and the light emitting diodes are identical or are of the same type of light emitting diodes. The method comprises the following steps: determining a reference voltage at the reference light emitting diode of the circuit arrangement and in each case a diode voltage at one of the light emitting diodes of the lighting unit by means of the voltage sensing unit, and detecting a short circuit in a light emitting diode on the basis of the reference voltage and a single diode voltage.

Thus, the inventive method has the same advantages as the ones described in detail with respect to the circuit arrangement according to the invention.

Furthermore, a method according to the invention can have the following steps: comparing the reference voltage to one of the diode voltages; detecting in each case a differential voltage between the reference voltage and the respective diode voltage based on the comparison; comparing the determined differential voltage to in each case a predefined threshold voltage; and detecting a short circuit in a light emitting diode when the differential voltage is greater than the threshold value.

To detect the short circuit, the reference voltage can be compared in each case with one of the diode voltages, wherein the determination of the reference voltage and a diode voltage and the associated comparison between the reference voltage and the diode voltages is performed together over a period of less than 100 ms, in particular less than 10 ms. As a result, self-heating and an associated temperature drift of the light emitting diodes can be prevented or at least substantially prevented.

As already described above for the circuit arrangement, it is furthermore possible within the scope of the method that the lighting unit is designed in the form of a vehicle headlight of a vehicle, wherein the determination of the reference voltage, the determination of the diode voltages and the detection of a possible short circuit are carried out when starting the vehicle. Accordingly, the lighting unit can be switched off by a shut-off unit on the basis of the reference voltage and a single diode voltage. On the basis of the reference voltage and a single diode voltage, a warning signal for switching off the lighting unit can be output by a signal output unit.

In accordance with another aspect of the invention, a computer program is provided that includes instructions that, when the computer program is executed by a computer, cause the latter to perform the method described above. The computer program may be implemented as a computer-readable instruction code in any suitable programming language such as JAVA, C++ or C#. The computer program may be stored on a computer-readable storage medium such as a data disk, a removable drive, a volatile or nonvolatile memory, or a built-in memory/processor. The instruction code may program a computer or other programmable device, such as a vehicle controller, to perform the desired functions. Further, the computer program may be provided in a network, such as the Internet, from which it may be downloaded by a user as needed. The computer program can be realized both by means of software and by means of one or more special electronic circuits, i.e., in hardware in the form of a computer program product, or in any hybrid form, i.e., by means of software components and hardware components.

In addition, a memory is provided with such a computer program stored on the memory. The memory may be configured as a data carrier in the form of a memory stick, a memory disk, a hard drive or even a control device or the like. In addition, the present invention comprises a vehicle having at least one lighting unit and a circuit arrangement as described above, which is configured and adapted to detect a short circuit in at least one light emitting diode of the lighting unit comprising a plurality of light emitting diodes connected in series, wherein the lighting unit is designed in the form of a vehicle headlamp. The lighting unit is designed in particular as a low beam of the vehicle.

Thus, the computer program according to the invention, the memory according to the invention and the vehicle according to the invention also offer the advantages described above.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a circuit arrangement according to a preferred embodiment of the present invention,

FIG. 2 shows a vehicle with a circuit arrangement as shown in FIG. 1

FIG. 3 shows a flow chart for explaining a method according to a preferred embodiment of the present invention, and

FIG. 4 shows an LED matrix manager with a circuit arrangement as shown in FIG. 1.

### DETAILED DESCRIPTION

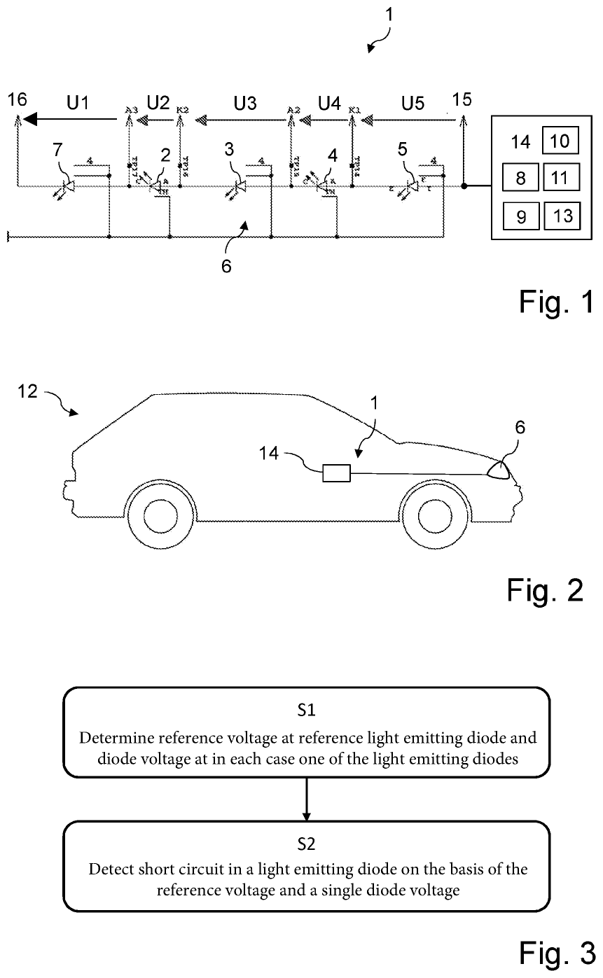

FIG. 1 shows a circuit arrangement 1 for detecting a short circuit in at least one light emitting diode 2, 3, 4, 5 of a lighting unit 6, which comprises several light emitting diodes 2, 3, 4, 5 connected in series. The circuit arrangement 1 furthermore has a reference light emitting diode 7 and a voltage sensing unit 8 for determining a reference voltage U1 at the reference light emitting diode 7 and in each case one diode voltage U2, U3, U4, U5 at one of the light emitting diodes 2, 3, 4, 5 of the lighting unit 6. That is to say, the voltage sensing unit is configured to determine a diode voltage U2 at a first light emitting diode 2, a diode voltage U3 at a second light emitting diode 3, a diode voltage U4 at a third light emitting diode 4, and a diode voltage U5 at a fourth light emitting diode 5. In addition, the circuit arrangement 1 has a detection unit 9 for detecting a short circuit in at least one of the light emitting diodes 2, 3, 4, 5 on the basis of the reference voltage U1 and a single diode voltage U2, U3, U4, U5. The reference light emitting diode 7 and the light emitting diodes 2, 3, 4, 5 are identical light emitting diodes or the reference light emitting diode 7 is of the same type as the light emitting diodes 2, 3, 4, 5 to be checked.

The detection unit 9 illustrated in FIG. 1 is configured and adapted to compare the reference voltage U1 with in each case one of the diode voltages U2, U3, U4, U5, to determine in each case a differential voltage between the reference voltage U1 and the respective diode voltage U2, U3, U4, U5 based on said comparison, to compare the determined differential voltage in each case with a predefined threshold voltage or a corresponding threshold value and to detect a short circuit in a light emitting diode 2, 3, 4, 5 when the differential voltage is greater than the threshold value.

The circuit arrangement 1 further has a shut-off unit 10 for switching off the lighting unit 6 on the basis of the reference voltage U1 and a single diode voltage U2, U3, U4, U5. Furthermore, the circuit arrangement 1 has a signal output unit 11 for outputting a warning signal for switching off the lighting unit 2 on the basis of the reference voltage U1 and a single diode voltage U2, U3, U4, U5.

According to the circuit arrangement 1 shown in FIG. 1, the voltage sensing unit 8, the detection unit 9, the shut-off unit 10 and the signal output unit 11 are integrated in a control device 14 in the form of a vehicle controller, in which further a computer program 13 is installed for implementing a method described later with reference to FIG. 3. The circuit arrangement 1 shown in FIG. 1 is in signal connection with an anode 15 and a cathode 16.

FIG. 2 shows a vehicle 12 with a control device 14 and two lighting units 6 in the form of two vehicle headlights. The vehicle has a circuit arrangement 1 as described above, which is configured and adapted to detect a short circuit in at least one light emitting diode 2, 3, 4, 5 of one of the lighting units 6.

FIG. 3 shows a flow chart for explaining a method for detecting a short circuit in at least one of the light emitting diodes 2, 3, 4, 5 of the lighting unit 6 according to a preferred embodiment. For this purpose, in a first step S1, a reference voltage U1 at the reference light emitting diode 7 of the circuit arrangement 1 and in each case one diode voltage U2, U3, U4, U5 at one of the light emitting diodes 2, 3, 4, 5 of the lighting unit 6 is determined by the voltage sensing unit 8. Subsequently, in a second step S2, a short circuit in one of the light emitting diodes 2, 3, 4, 5 can be detected on the basis of the reference voltage U1 and a single diode voltage U2, U3, U4, U5.

According to a preferred embodiment, for this purpose the reference voltage U1 is compared with one of the diode voltages U2, U3, U4, U5, in each case a differential voltage between the reference voltage U1 and the respective diode voltage U2, U3, U4, U5 is determined based on said comparison, the determined differential voltage is in each case compared with a predefined threshold voltage, and a short circuit in a light emitting diode 2, 3, 4, 5 is detected when the differential voltage is greater than the threshold value.

The determination of the reference voltage U1 and a diode voltage U2, U3, U4, U5 and the associated comparison between the reference voltage U1 and the diode voltages U2, U3, U4, U5 are performed together over a period of less than 100 ms. The determination of the reference voltage U1, the determination of the diode voltages U2, U3, U4, U5 and the detection of a possible short circuit are performed when starting the vehicle 12.

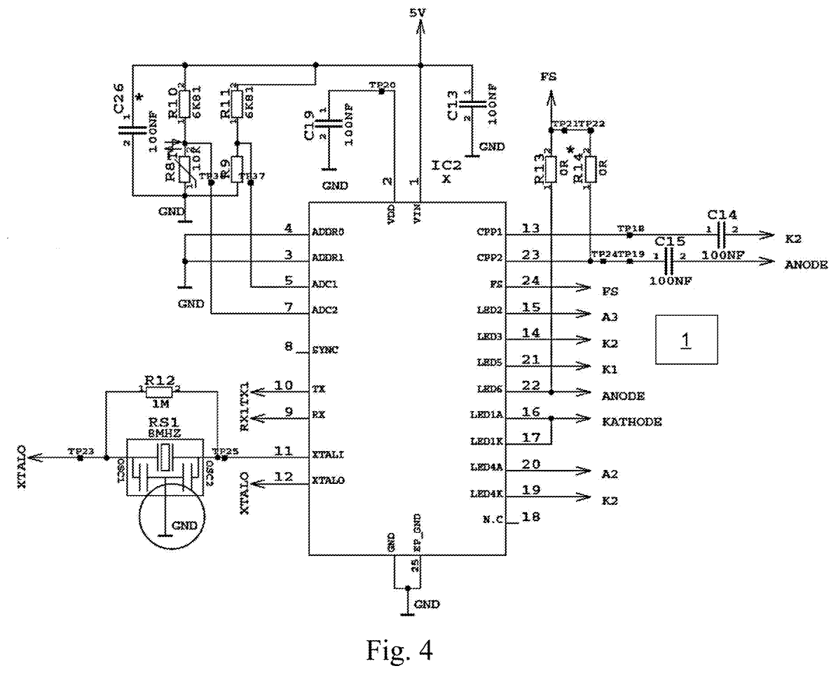

FIG. 4 shows an LED matrix manager with a circuit arrangement 1 integrated therein, as has been described in detail above.

In addition to the illustrated embodiments, the invention allows for further design principles. That is, the invention should not be considered to be limited to the embodiments explained with reference to the figures.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

1. A circuit arrangement for detecting a short circuit in at least one light emitting diode of a lighting unit of a vehicle, the circuit arrangement comprising:
a plurality of light emitting diodes connected in series;
a reference light emitting diode;
a voltage sensing unit to determine a reference voltage at the reference light emitting diode and at least one diode voltage at one of the light emitting diodes of the lighting unit; and
a detection unit to detect a short circuit in a light emitting diode based on the reference voltage and a single diode voltage,
wherein the reference light emitting diode and the light emitting diodes are identical light emitting diodes.

2. The circuit arrangement according to claim 1, wherein the detection unit is configured and adapted to compare in each case the reference voltage with one of the diode voltages to determine a differential voltage between the reference voltage and the respective diode voltage based on said comparison, to compare the determined differential voltage with a predefined threshold voltage and to detect a short circuit in a light emitting diode when the differential voltage is greater than the threshold value.

3. The circuit arrangement according to claim 1, wherein the circuit arrangement has a shut-off unit for switching off the lighting unit based on the reference voltage and a single diode voltage.

4. The circuit arrangement according to claim 1, wherein the circuit arrangement has a signal output unit for outputting a warning signal for switching off the lighting unit based on the reference voltage and a single diode voltage.

5. A method for detecting a short circuit in at least one light emitting diode of a lighting unit of a vehicle, the method comprising:
providing a plurality of light emitting diodes connected in series via a reference light emitting diode, the reference light emitting diode and the light emitting diodes being identical light emitting diodes;
determining a reference voltage at the reference light emitting diode of the circuit arrangement and a diode voltage at one of the light emitting diodes of the lighting unit via a voltage sensing unit; and
detecting a short circuit in a light emitting diode based on the reference voltage and a single diode voltage.

6. The method according to claim 5, further comprising:
comparing the reference voltage to one of the diode voltages;
determining a difference voltage between the reference voltage and the respective diode voltage based on the comparison;
comparing the determined differential voltage with a predefined threshold voltage; and
detecting a short circuit in a light emitting diode when the difference voltage is greater than the threshold value.

7. The method according to claim 5, wherein, for detecting the short circuit, the reference voltage is compared to one of the diode voltages, wherein the determination of the reference voltage and a diode voltage as well as the associated comparison between the reference voltage and the diode voltages are performed together over a period of less than 100 ms.

8. The method according to claim 5, wherein the lighting unit is a vehicle headlight of a vehicle, and wherein the determination of the reference voltage, the determination of the diode voltages and the detection of a possible short circuit are performed when starting the vehicle.

9. The method according to claim 5, wherein the lighting unit is switched off by a shut-off unit based on the reference voltage and a single diode voltage.

10. The method according to claim 5, wherein a warning signal for switching off the lighting unit is output by a signal output unit based on the reference voltage and a single diode voltage.

11. A computer program comprising instructions which, when the computer program is executed by a computer, cause the computer to perform the method according to claim 5.

12. A memory with a computer program stored thereon according to claim 11.

13. A vehicle comprising:
at least one lighting unit; and
a circuit arrangement according to claim 1, the circuit arrangement being configured and adapted to detect a short circuit in at least one light emitting diode of the lighting unit, which comprises a plurality of light emitting diodes connected in series, wherein the lighting unit is a vehicle headlight.
